(19) United States
(12) Patent Application Publication
(10) Pub. No.: US 2025/0087417 A1
(43) Pub. Date: Mar. 13, 2025

(54) Method and Apparatus for Increasing Skin Depth and Reducing Eddy Currents in Magnetic Metal-Based Materials Having Porous Insulation Layers by Using Metallic Ink Plating Techniques

(71) Applicant: Atlas Magnetics, Reno, NV (US)

(72) Inventor: John Othniel McDonald, Reno, NV (US)

(21) Appl. No.: 18/960,991

(22) Filed: Nov. 26, 2024

Related U.S. Application Data
(63) Continuation-in-part of application No. 18/131,350, filed on Apr. 5, 2023.
(63) Continuation-in-part of application No. 18/135,660, filed on Apr. 17, 2023.
(60) Provisional application No. 63/604,382, filed on Nov. 30, 2023.

(51) Int. Cl. H01F 41/14; C23C 16/40; C23C 28/00; C25D 5/54; C25D 7/00; H01F 27/24

(52) U.S. Cl. CPC H01F 41/14; C23C 16/402; C23C 28/321; C23C 28/34; C25D 5/54; C25D 7/001; H01F 27/24

(57) ABSTRACT

The present invention presents a method for reducing Hysteresis core loss and Eddy current core loss for magnetic components or materials integrating a porous insulation layer and the resulting apparatus. A metallic layer is formed, and a porous insulation layer is deposited. The insulation deposition is followed by the formation of an ink coverage layer which seals the voids of the porous insulation layer so that they become gaps. The ink coverage layer may be built upon to form subsequent component layers. The result is a component with a gapped porous insulation layer where the voids increase the insulation the porous insulation layer provides. This increases the directional impedance of the magnetic material or core while retaining the thinness of the layers, both insulation and metallic, that the use of porous insulation layers allows.

### CROSS-REFERENCE TO RELATED APPLICATIONS

This application is a continuation-in-part of U.S. patent application Ser. No. 18/131,350, filed Apr. 5, 2023 which claims the benefit of U.S. Provisional Patent Application No. 63/327,789, filed Apr. 5, 2022; and U.S. patent application Ser. No. 18/135,660, filed Apr. 17, 2023 which claims the benefit of provisional 63/337,078, filed Apr. 30, 2022 and provisional 63/331,761, filed Apr. 15, 2022 and is itself a continuation-in-part of U.S. patent application Ser. No. 17/900,803. It also claims the benefit of provisional 63/604,382, filed Nov. 30, 2023. Each of these applications is incorporated by reference herein in its entirety.

### BACKGROUND

Processes of layering a metal with thin, perfect layers of insulation to reduce eddy currents or “core loss” in the case of power transformers and inductors have been in production since 1885. Today, power designers seek to shrink the size, cost, and weight of power devices and are often limited by the requirements of the magnetic devices in the system. One of the most straightforward methods to reduce the size of the magnetic components is to increase the frequency of operation where roughly speaking, every 2× increase in frequency results in a 2× decrease in the required inductance.

Increasing frequency without reducing core performance means that insulation layering must get thinner. This has created an economic problem as fine layering requires either expensive precision deposition equipment with relatively low-speed deposition techniques and heavy use of photoresist, mask, or dry film for patterning, often with one or more patterning steps per layer or imprecise high-speed plating, with once again, one or two uses of dry film per layer which in turn drives up the cost of the product to the point where the products exist only for niche applications which are able to justify the high cost.

Methods of insulation deposition such as Chemical Combustion Vapor Deposition (CCVD) or Open-Air Atmospheric Pressure Plasma Enhanced Chemical Vapor Deposition (AP-PECVD) result in a porous insulation layer. Other methods, including printing the insulation layer, may be used to form a porous insulation layer. A porous insulation layer can be used to dramatically lower the cost of embedding a layer of insulation material into a composite metal.

In CCVD, the cost reduction is accomplished by, for example, a silicon dioxide (SiO₂) precursor chemical being ignited by a burner flame, causing a chemical reaction that creates hot SiO₂ nanoparticles. The SiO₂ particles are expelled onto the target object of the deposition, forming a layer. The newly formed SiO₂ falls onto the object and forms a layer of randomly distributed SiO₂. As more product falls, the SiO₂ layer increases in thickness. By controlling the thickness and spread of the SiO₂, the percentage coverage of the prior metal layer by SiO₂ can be controlled to some degree but is currently always less than 100%. The lack of perfect coverage means that the SiO₂ layer will be a “porous” insulative layer. In microelectronics manufacturing, the porosity of the insulation layer provides significant benefits, as the voids of the SiO₂ layer allow metal layers to be electroplated through the SiO₂ layer. Therefore, in plating methods incorporating CCVD, there are no additional steps besides washing and drying steps between the plating of a metal layer and the deposit of the SiO₂ insulation.

The benefits of the porous layer of SiO₂ are mainly related to the ease of forming a composite material with insulative layers, which greatly reduces cost as compared to the additional processing steps required to prepare a SiO₂ insulative layer for electroplating using alternative methods. The porous insulation layers may be placed closely together, resulting in a thinner insulation layer.

A porous CCVD-deposited SiO₂ layer is enough of an insulator to reduce losses due to eddy currents to an economically competitive level, even in high-frequency current applications. Further, the process of depositing the porous SiO₂ layer, even though deposited at high temperature, is compatible with low-temperature materials such as dry film, photoresist, and various other epoxies and materials used on wafers, semiconductor packaging, and printed circuit boards during manufacturer or as a part of the end product due to only a few seconds at the high temperature being required for deposition.

However, the SiO₂ layer is a porous layer and, thus, a poor insulator. Therefore, it may be beneficial to increase the insulative strength of the porous layers further in applications where further reduction in not only eddy currents but any current flowing perpendicular to the layering in the composite material while keeping resistivity low for currents flowing parallel to the layering is beneficial.

### BRIEF SUMMARY OF THE INVENTION

The present invention presents a method for manufacturing a porous insulation layer in the CCVD or AP-PECVD style with increased insulative strength and the resulting apparatus. The method increases the SiO₂ layer's insulation strength without resorting to relatively expensive insulating polymers, epoxy films, coatings applied at temperatures, pressures, or processes that are incompatible with semiconductor packaging epoxy plastics, semiconductor wafers, or printed circuit boards. In at least one exemplary embodiment, the apparatus is a porous SiO₂ layer with increased insulative properties. The resulting components include but are not limited to nickel-iron wiring or traces with porous insulation layers. The increased insulative strength will increase the ability of the SiO₂ layers to reduce eddy current formation and thus provide a greater skin depth for the materials it is integrated into.

The method comprises depositing a SiO₂ layer by a porous deposition process onto a metal layer of an electrical component. The formation of the SiO₂ layer is followed by the placing of a metallic ink or paste. The metal ink is initially deposited as spheres; these spheres are subjected to heat, which at least partially melts the spheres connecting them and forming a layer. When these spheres are dropped onto a porous SiO₂ layer, in the typical case, the sphere will not fill the SiO₂ voids but will sit above it so that the spheres cover the porous SiO₂ layer. Given the shape of the spheres, there are voids between the spheres of the SiO₂ and the spheres of the metal ink. These voids are above and beyond the voids which form directly from voids of the SiO₂ layer. The metal ink spheres are heated, deform under heat, and form a covering layer over the SiO₂ layer-but bonded to it-leaving, for the most part, the voids of the SiO₂ layer covered-not filled, as well as providing new voids given the initial starting shape and location of the metal ink spheres and their deformity under heat.

The resulting apparatus is a nickel-iron component or component part with a porous insulation layer. Unlike a porous layer where electroplated metal or electroless plated metal is deposited immediately next, the porous insulation layer, with its tiny nanometer-sized voids, is not entirely filled nor are they pinched-but they are covered, or it could be said, capped.

The covered voids may contain air, liquid, and oxide of the nearby metals and, in most cases, contain some aspect of the plating or pre-plating environment. The voids' resistance is much higher than the resistance of nickel-iron or other metals, which would otherwise fill the voids as in the case of standard electroplating deposition. The voids' resistance is much higher than the resistance of electroless-ly pinched voids. Further, there are more voids, and voids may be larger as they are not partially pinched or filled. Thus, the insulative properties in a CCVD or AP-PECVD Ink-formed metal structure or material are greater than in a pinched or filled SiO₂ layer.

Therefore, this invention may include a method of producing hybrid ink material comprising; having at least one first magnetic metallic layer, depositing a porous insulation layer onto the first metallic layer, and forming an ink coverage layer over the porous insulation layer.

The hybrid ink material comprises; a metallic magnetic layer, and at least one ink-covered SiO₂ particle layer is embedded in the metallic layer. Because the ink used to cover the porous insulation layer may be of the same material as the first magnetic metallic, the effect, even with a single ink layer and no subsequent layers, may be a single hybrid ink material.

However, further layers may be created by repeating each of the steps of the method, where each ink coverage layer becomes a new first metallic layer or electroplating additional metallic layers onto the ink layer already on the surface of the insulation and then repeating the steps of the method where the electroplated metallic layer serves as the first metallic magnetic layer.

As silicon dioxide (SiO₂) is used to make porous insulation layers in at least one embodiment, the porous insulation layer is composed of SiO₂. The ink of the ink coverage layer may contain, in at least one exemplary embodiment, palladium, nickel-iron, nickel, nickel-phosphorus, silver, aluminum, iron, cobalt, titanium, or any alloy of any of these materials. In at least one embodiment, any random combination, fixed ratio, or algorithmic defined pattern of ink insulation coverage versus electroplated coverage of the porous insulation layer may be used.

In many applications, it is useful that the metallic layer be nickel-iron, especially wherein the metallic magnetic layers are configured by patterning into a magnetic core.

In at least one embodiment, the first magnetic metallic layer has been formed on and is still connected to a substrate core, carrier, silicon wafer, or film, and the resulting apparatus is a single or double-sided metal-clad substrate core wherein the core is composed of one or more of the following: epoxy, fiberglass, Ajinomoto Build-Up film, silicon, or polymers. The core composition may be selected for enhanced mechanical, thermal, electrical, or cost properties.

The metal-clad substrate core or the hybrid ink material itself may be subjected to subtractive manufacturing processes without special consideration for the porous insulation layer.

### BRIEF DESCRIPTION OF THE FIGURES

FIG. 1 is a cross-section view of a porous insulation layer on a metal.

FIG. 2 is a cross-sectional view of ink spheres deposited on a porous insulation layer.

FIG. 3 is FIG. 2 is a cross-sectional view of deformed ink spheres deposited on a porous insulation layer.

FIG. 4 is a cross-sectional view of a porous insulation layer void that has been covered by ink spheres.

FIG. 5 is a cross-sectional view of a porous insulation layer void that has been covered by ink spheres that have been heated and deformed.

FIG. 6 is a cross-sectional view of a porous insulation layer void of FIG. 5 surrounded by nickel-iron.

FIG. 7 is a cross-sectional view of a porous insulation layer void that has been partially filled by ink spheres.

FIG. 8 is a cross-sectional view of a porous insulation layer void that has been partially filled by ink spheres.

FIG. 9 is a cross-section view of a plated metallic magnetic layer on an initial ink layer.

FIG. 10 is a flow chart showing cross-sectional views of each step of a subtractive component manufacturing process incorporating the method of the present invention.

FIG. 11 is a flow chart showing cross-sectional views of each step of an additive component manufacturing process incorporating the method of the present invention.

### DETAILED DESCRIPTION OF INVENTION

The present invention involves a novel method of plating electrical components with a porous insulation layer through a CCVD, AP-PECVD process, or other methods of forming a porous insulation layer. Although CCVD and AP-PECVD currently present the best modes, other forms of creating porous insulation include but are not limited to Duty Cycle plating, which cycles a metal through an oxidative environment and a plating bath, and printing plating processes, which can print a porous insulation layer. These methods are modified by the inclusion of an ink deposition step after the insulation layer is formed, which seals a portion, if not all, of the voids of the porous insulation layer, creating a gapped porous insulation layer.

Here the methods will be referred to in general as a hybrid ink method, the resulting material from the methods of the present invention will be referred to as a hybrid ink material, and the resulting components will be referred to as a hybrid ink component.

In general, hybrid materials, have thin layers of insulation that the primary layers may pierce and connect through, have enabled the manufacture of small high-frequency magnetics at practical costs for their incorporation into consumer electronic devices. Inductors with hybrid materials windings or cores offer high performance and can bring this performance to many systems.

In more detailed terms, for the purposes of this patent, a hybrid material is a material used in the microelectronics industry having at least one internal porous insulative layer, and wherein, there is a material filling some of the pores of the insulative layer; alternatively a hybrid material is a material in which insulative material and the magnetic material are mixed heterogeneously, homogeneously, or in layers. In general, the hybrid materials are electroplated, and the insulative layer is placed by a pore-forming method. The pores of the insulative layer allow the next material plating step, whether that is electroplating, electroless plating, metal ink plating, or metal printing, to occur without intermediary steps. The present invention presents a hybrid material wherein some of the pores are filled with air or other environmental materials when covered or pinched off by the hybrid ink process.

The hybrid ink method is particularly useful for enabling high-frequency capable components by providing a robust, low-cost insulation layer capable of reducing eddy currents and thus increasing the effective skin depth of the component. This method is beneficial for creating high-frequency GHz-rated magnetic components, for example, nickel-iron components, including magnetic cores. Additionally, the high-resistivity hybrid ink method of depositing the insulation layer of the present invention may be used with but is not limited to being used with electroplating or electroless plating methods.

The hybrid ink method is used to form a novel magnetic material. While the preferred hybrid Ink infused material is thus nickel-iron and various nickel-iron surface preparation materials such as palladium. Many materials that are available for electroless or electrodeposition, such as but not limited to nickel, nickel-phosphorus, and their various material formulas for surface preparation, may be used and, in some applications, might be the preferred choice as some of these materials have higher resistivity or other superior mechanical, electrical or thermal properties which may prove more economically viable as compared to nickel-iron. The porous insulation layer may be any insulation that is compatible with the processes of forming a porous insulation layer that may be gapped by the hybrid method. In at least one exemplary embodiment insulation layer is a SiO₂ insulation layer. The metal ink of the hybrid method is to be the metal ink suitable to bond with the insulation layer or the metals or metal used or both and is a conductive in at least one embodiment of the present invention.

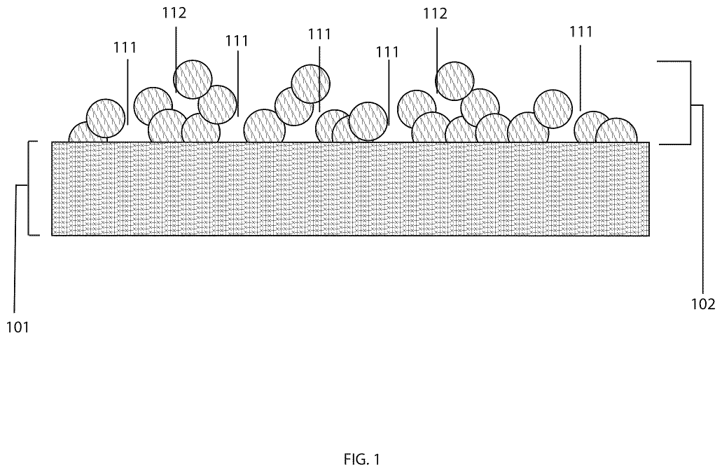

FIG. 1 shows a metal layer 101 having a SiO₂ particle layer 102 on its upper surface. The metal layer 101 may be nickel-iron or any plateable metal. In the exemplary embodiment demonstrated by FIG. 1, it is nickel-iron. This SiO₂ particle layer 102 has been randomly distributed through CCVD or AP-PECVD processes and thus comprises randomly formed molecular clumps (particulates) of SiO₂. The SiO₂ particulates making up the SiO₂ layer 102 may thus form a layer in any pattern, and this figure is only demonstrative of one pattern the SiO₂ particles may form. Note that some SiO₂ particles embed in the metal layer due to their heat as combustion products. Also, in practice, the SiO₂ particulates may take any shape as dictated by their molecular structure and environmental interactions.

There are several large through voids 111 between the SiO₂ particles. These voids 111 present through voids that transverse the entire cross-section of the SiO₂ layer 102. Other significant voids 112 may also exist, which do not transverse the entire cross-section of the SiO₂ layer 102.

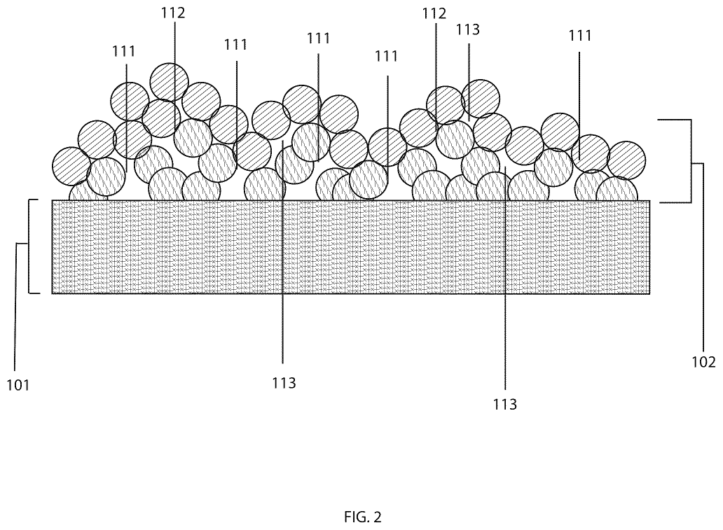

FIG. 2 shows a metal ink deposited onto the SiO₂ layer 102 and the nickel-iron layer 101 of FIG. 1. Here, the metal ink is nickel-iron ink. The metal spheres of the ink can be seen resting on the upper portions of the SiO₂ surfaces. There are new voids formed between the sphere of the metal ink and the spheres of the SiO₂. During the heating and bonding process, some of these new voids will be filled; however, some will remain. Significantly, new voids 113 will remain after the heating process.

Thus the 111 voids and the 112 voids have been covered by spheres, and new voids 113 have been formed. (It should be noted that although shown as a different color than the nickel-iron layer, the ink sphere's nickel-iron is still the same material.)

Voids closed off by the ink coverage layer may contain some environmental material. The environmental material could be controlled by controlling the plating or pre-plating environment.

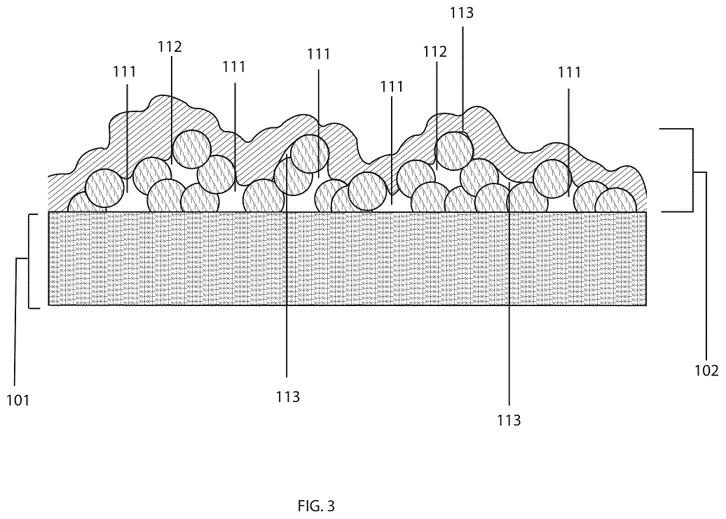

The ink spheres may be heated to bond them to the SiO₂ and, in such a process, will be deformed. The deformities will further close off the voids between the SiO₂ particulates, as shown in FIG. 3. In FIG. 3 the spheres are now deformed, but the ink now completely covers voids 111 and 112. Voids 113 have been partially filled but still remain. Thus, the porous insulation layer has become a gapped porous insulation layer.

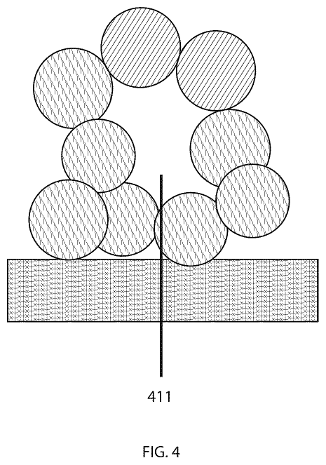

FIG. 4 focuses on a demonstrative SiO₂ void 411 that is not a through SiO₂ void and is wider than a single metal sphere at the top. The top of void 411 has two metal spheres that cover the gap.

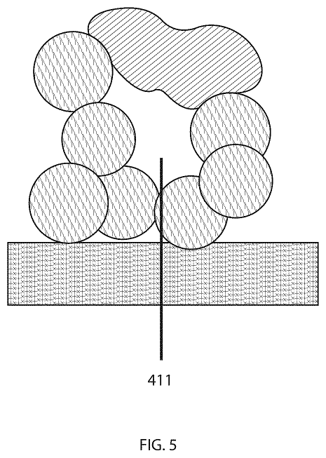

FIG. 5 shows the spheres of FIG. 4, after a heating process, are now deformed but cover the gap. This prevents subsequent metal plating from filling the gap, and thus void 411 will not contain metal.

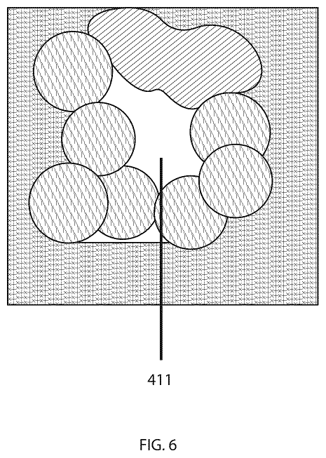

FIG. 6 shows that the nickel-iron ink cover layer will prevent subsequent plating from reaching void 411—leaving the void unfilled.

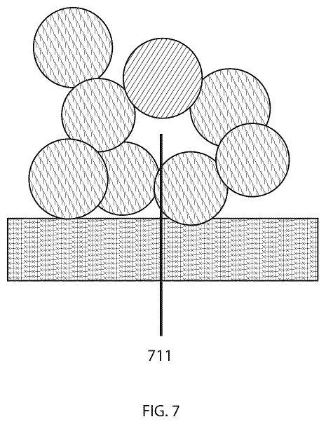

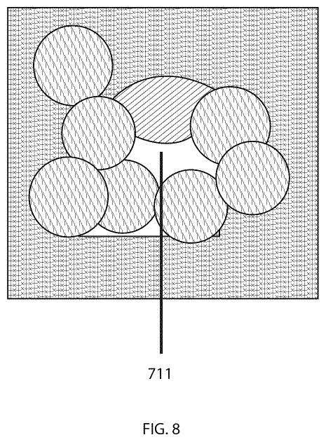

As shown in FIG. 7, in some cases, a sphere will fall into the void and partially fill the gap, as shown in void 711. As shown in FIG. 8, This will mean less void 711 space is unfilled when compared to a fully covered void 411, as in FIG. 6.

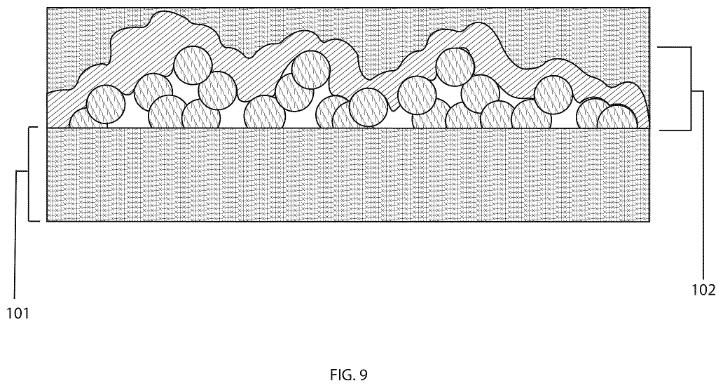

FIG. 9 shows the SiO₂ layer from FIG. 2 now having the subsequent metal layer built upon it. This layer may be built but is not limited to being built by electroplating or e'less plating. The steps as shown in FIG. 1, FIG. 2, and FIG. 3 may be repeated until the desired component has been built.

The porous insulation layer of the present invention is porous and when it consists of loose silicon dioxide particulates embedded in the nickel-iron—it is not a complete single-piece silicon dioxide layer. As such, in particulate form, it is very susceptible to subtractive manufacturing processes, including etching and drilling. In subtractive manufacturing processes, the silicon dioxide behaves in a dust-like manner: in etching processes, for example, the silicon dioxide particulates are washed away, and in drilling processes, the silicon dioxide does not present a resistive barrier to the drill and is cleared with magnetic material as drill dust.

In regard to acid etches, because this silicon dioxide layer exists in particulate form with through-voids, the etching acid will etch through the silicon dioxide voids. This property allows any etching acid to be used, which is useful for etching the metal around the silicon dioxide. Thus, HF acid often required for etching glass need not be used.

Because of the ease of integrating the silicon dioxide layers into substrate manufacturing workflow, it is useful for building substrate cores with magnetic cladding. The core may be single-clad or double-clad and may be, but is not limited to, an epoxy, fiberglass, Ajinomoto Build-Up film, silicon, polymers, various films core, or any core or core similar to what is in use in the printed circuit board, semiconductor packaging, a semiconductor wafer, or lamination industry

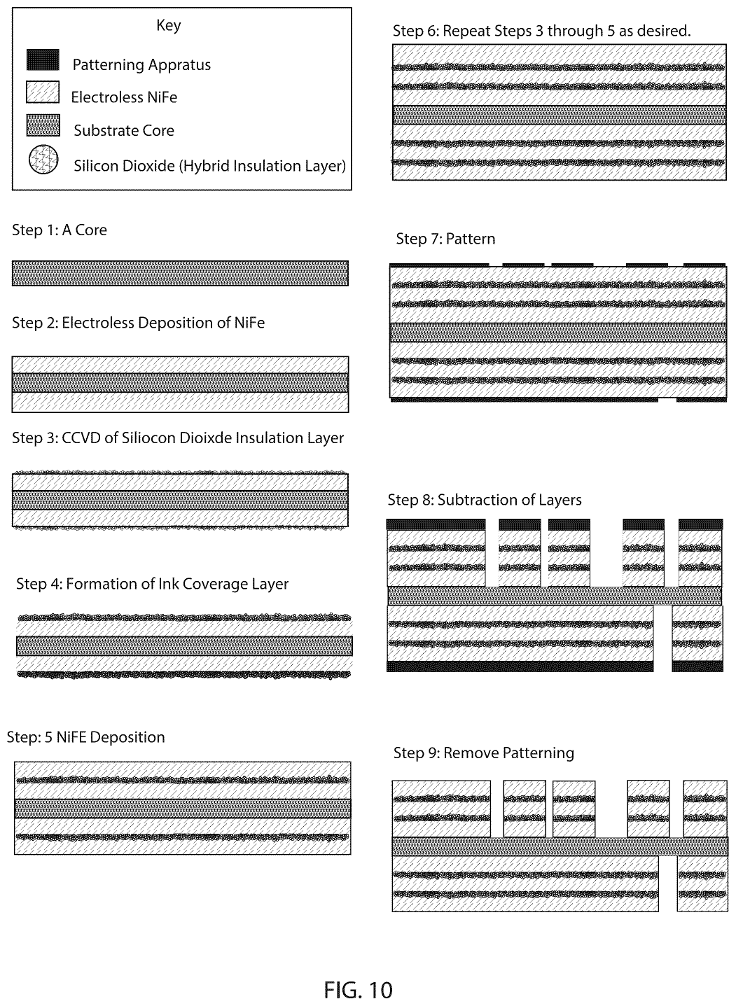

FIG. 10 shows an overview of the general processes of the invention incorporated into a plating workflow where a substrate core with nickel-iron cladding is created and then etched.

Step 1 shows the starting core, which will be sheathed with nickel-iron cladding. Step 2 shows an initial nickel-iron cladding layer deposited onto the core. Both sides of the substrate core may be sheathed with the first nickel-iron layer and all subsequent layers.

After the first nickel-iron layer is deposited, a porous particulate insulation layer is deposited, as shown in Step 3. An ink layer is then deposited as metal ink, as shown in Step 4, and this is covered by a nickel-iron deposition in Step 5. Steps 3, 4, and 5 may be repeated until a desired number of layers is completed, and the final outcome of one number of such repetitions is shown in Step 6.

This completes the nickel-iron-cladding core. However, to demonstrate the ease of subtractive manufacturing, a subtractive workflow is included in FIG. 10, where Step 7 shows a pattern put in place for a subtractive process. Step 8 shows the subtractive process carried out, and Step 9 shows the pattern removed and the process completed. There is no need for extra steps for the core with silicon dioxide-infused cladding that a normal subtractive process for a non-CCVD-based core would otherwise not need.

The steps in FIG. 10 can be done with any plateable metal which has a bondable metal ink. Thus, components can be made of many metals or alloys, including nickel-iron and aluminum.

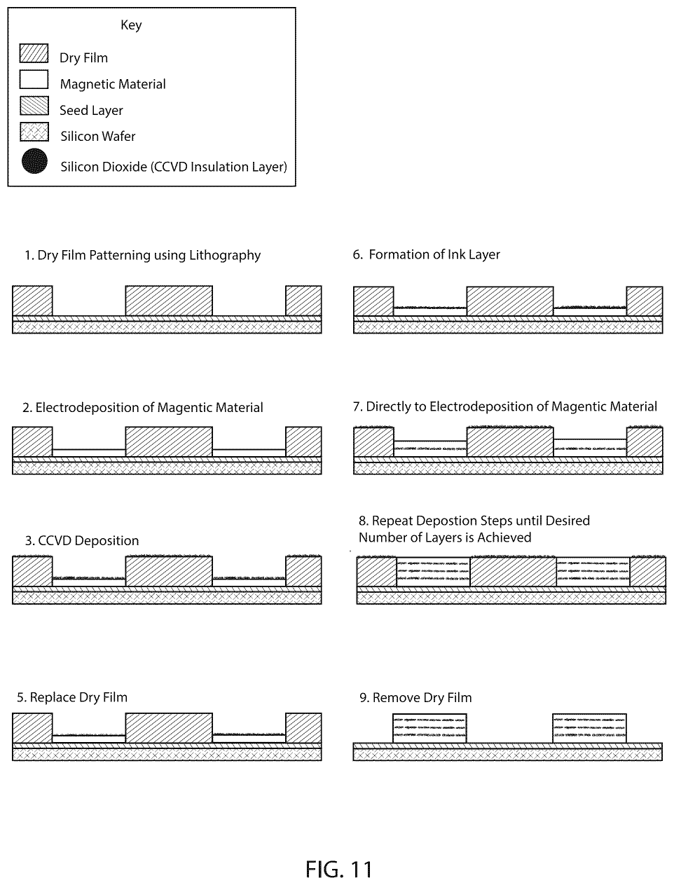

Hybrid ink plating presents a simple method of creating a base for components to be formed out of by a subtractive method, usually involving but not limited to chemical etching, laser drilling or cutting, or mechanical drilling or cutting. However, a positive manufacturing process is more complicated as after each ink-plating step, the dry film would have to be removed. This process is shown in FIG. 11.

Here, there is a dry film replacement step after each CCVD event. This prevents the buildup of SiO₂ on the dry film walls and the subsequent bonding of ink with SiO₂ from the ink layer formation on the walls of the dry film. Such a build-up would provide an insulation layer that runs perpendicular to the intended current or flux pathways and reduce the device's performance. However, as this effect may be minimal, at least one exemplary embodiment of the present invention does not include a dry film replacement.

In all cases of gapped porous insulation layers and components, once the component or layer is built, it may be beneficial to shock it. In at least one exemplary embodiment, the resulting component is subject to a shocking process, which may be a thermal shock process.

Hybrid ink cores may be stacked with other hybrid ink cores or with other cores in general. Non-porous forms of insulation may be used between each core in the stack of cores. A hybrid Ink core or material itself may include at least one non-porous form of insulation as an insulating layer.

The drawings and figures show multiple embodiments and are intended to be descriptive of particular embodiments but not limited to the scope, number, or style of the embodiments of the invention. The invention may incorporate a myriad of styles and particular embodiments. All figures are prototypes and rough drawings: the final products may be more refined by one skill in the art. Nothing should be construed as critical or essential unless explicitly described as such. Also, the articles “a” and “an” may be understood as “one or more.” Where only one item is intended, the term “one” or other similar language is used. Also, the terms “has,” “have,” “having,” or the like are intended to be open-ended terms. The term “metal” is defined as a metal or an alloy thereof.

1. A method of producing hybrid ink material comprising;
having at least one first magnetic metallic layer;
depositing a porous insulation layer onto the first magnetic metallic layer; and
forming an ink coverage layer over the porous insulation layer.

2. The method of claim 1, further comprising electroplating an additional metallic layer onto the ink coverage layer.

3. The method of claim 1, further comprising repeating each of the steps of the method, where each ink coverage layer becomes a new first magnetic metallic layer.

4. The method of claim 1, wherein the porous insulation layer is composed of SiO₂.

5. The method of claim 1, wherein the magnetic metallic layer is nickel-iron.

6. The method of claim 1, further comprising subjecting the layers to a subtractive manufacturing process.

7. The method of claim 1, wherein the ink contains palladium, copper, nickel, nickel-phosphorus, nickel-iron, silver, aluminum, iron, cobalt, titanium or any alloy of any of these materials.

8. The method of claim 1, wherein the layers are patterned into a magnetic core.

9. The method of claim 1, further comprising any random combination, fixed ratio, or algorithmic defined pattern of ink insulation coverage versus electroplated coverage of the porous insulation layer.

10. The method of claim 1, further comprising the first magnetic metallic layer having been formed on and still being connected to a substrate core, carrier, silicon wafer, or film.

11. The method of claim 10, wherein the resulting apparatus is a single or double-sided metal-clad substrate core wherein the core is composed of one or more of the following: epoxy, fiberglass, Ajinomoto Build-Up film, silicon, or polymers.

12. The method of claim 11, further comprising selecting the core composition for enhanced mechanical, thermal, electrical or cost properties.

13. A porous insulation layer apparatus comprising;
at least one magnetic metallic layer; and
at least one ink gapped porous insulation layer embedded in the magnetic metallic layer.

14. The apparatus of claim 13, wherein the layers form a wire, trace, or ground plane.

15. The apparatus of claim 13, further comprising a substrate core, carrier, silicon wafer, or film operably connected to a surface of the magnetic metallic layer.

16. The apparatus of claim 13, wherein at least one magnetic metallic layer contains palladium, copper, nickel, nickel-phosphorus, silver, aluminum, iron, cobalt, titanium or any alloy of any of these materials.

17. The apparatus of claim 13, wherein the ink gapped porous insulation layer is composed of SiO₂.

18. The apparatus of claim 13 wherein the embedded ink gapped porous insulation layer does not fully delineate the magnetic metallic layer.

19. The apparatus of claim 13, further comprising a second magnetic metallic layer with at least one ink gapped porous insulation layer embedded within, operably connected to the surface of the substrate core opposite the first magnetic metallic layer.

20. The apparatus of claim 19, wherein the apparatus is a double-sided metal-clad substrate core, and wherein the core is composed of one or more of the following: epoxy, fiberglass, Ajinomoto Build-Up film, silicon, or polymers.

21. The apparatus of claim 13, further comprising a non-porous form of insulation operably embedded in at least one magnetic material layer.
